(19) United States
(12) Patent Application Publication
(10) Pub. No.: US 2013/0256666 A1
(43) Pub. Date: Oct. 3, 2013

(54) THIN FILM TRANSISTOR AND MANUFACTURING METHOD THEREOF

(71) Applicants: Hui-Yu Chang, Changhua County (TW); Ming-Chang Yu, Taichung City (TW); Chang-Ching Chiou, Taichung City (TW); Hsi-Rong Han, Taichung City (TW)

(72) Inventors: Hui-Yu Chang, Changhua County (TW); Ming-Chang Yu, Taichung City (TW); Chang-Ching Chiou, Taichung City (TW); Hsi-Rong Han, Taichung City (TW)

(73) Assignees: WINTEK CORPORATION, Taichung City (TW); Dongguan Masstop Liquid Crystal Display Co., Ltd., Dongguan City (CN)

(21) Appl. No.: 13/846,896

(22) Filed: Mar. 18, 2013

(30) Foreign Application Priority Data
Mar. 28, 2012 (TW) 101110788

(51) Int. Cl. H01L 29/786; H01L 29/66

(52) U.S. Cl. CPC H01L 29/78693; H01L 29/66765
USPC 257/57; 438/158

(57) ABSTRACT

A thin film transistor and a manufacturing method thereof are provided. The thin film transistor includes a gate, an oxide channel layer, a gate insulating layer, a source, a drain and a dielectric layer. The gate is disposed on a substrate. The oxide channel layer, disposed on the substrate, is stacked with the gate. A material of the oxide channel layer includes a metal element. The metal element content shows a gradient distribution along a thickness direction of the oxide channel layer. The gate insulation layer is disposed between the gate and the oxide channel layer. The source and the drain are disposed in parallel to each other, and connected to the oxide channel layer. Sides of the source and the drain, facing away from the substrate, are covered by the dielectric layer.

### CROSS-REFERENCE TO RELATED APPLICATION

This application claims the priority benefit of Taiwan application serial no. 101110788, filed on Mar. 28, 2012. The entirety of the above-mentioned patent application is hereby incorporated by reference herein and made a part of this specification.

### BACKGROUND OF THE DISCLOSURE

1. Field of the Disclosure

The invention relates to a semiconductor device and a manufacturing method thereof, and more particularly to a thin film transistor and a manufacturing method thereof.

2. Description of Related Art

With the proceeding improvement of the electronic technology, thin film transistor liquid crystal displays (TFT-LCD) have recently become a mainstream product in the display market due to the advantages such as high image quality, great space efficiency, low power consumption and no radiation.

Owing to the requirement of the TFT-LCD on large area and high resolution, the TFT therein needs have high carrier mobility so as to reduce the charge-discharge time. Generally, for the consideration of high carrier mobility, flexibility, and uniformity, the channel layer of the TFT is selectively manufactured by semiconductor oxide layer so as to be named as an oxide channel layer.

Generally, during manufacturing the TFT, several film layers are patterned through the processes including the ultraviolet (UV) light irradiation and the etching. However, the oxide channel layer is sensitive to water, oxygen, acid etchant or the like so that any change in the environment during the manufacturing process can change the characteristic of the oxide channel layer, which influences on the element characteristic of the TFT. In addition, the photo current generated by the oxide channel layer under the UV light irradiation would shorten the lifetime of the TFT and deteriorate the element characteristic of the TFT. Accordingly, to improve the stability of the oxide channel layer and diminish the influence of the environment on the oxide channel layer during the manufacturing process is an important issue.

### SUMMARY OF THE DISCLOSURE

The invention provides a thin film transistor having desirable electro-optical characteristic and stability and further provides a manufacturing method thereof.

The invention is directed to a thin film transistor including a gate, an oxide channel layer, a gate insulation layer, a source, a drain, and a dielectric layer. The gate is disposed on a substrate. The oxide channel layer disposed on the substrate is stacked with the gate in a top and bottom manner, wherein a material of the oxide channel layer includes a metal element and the metal element content has a gradient distribution in a thickness direction of the oxide channel layer. The gate insulation layer is disposed between the gate and the channel layer. The source and the drain are configured parallel to each other and electrically connected to the oxide channel layer. The dielectric layer covers the source and the drain at a side away from the substrate.

The invention is also directed to a manufacturing method of a thin film transistor including at least the following steps. A gate is formed on a substrate. At least one first semiconductor oxide layer and at least one second semiconductor oxide layer are formed on the substrate, wherein the at least one first semiconductor oxide layer and the at least one second semiconductor oxide layer are alternately arranged to form an oxide channel layer. The oxide channel layer is disposed on the substrate and stacked with the gate in a top and bottom manner, wherein a material of the oxide channel layer includes a metal element, and the metal element content has a gradient distribution in a thickness direction of the oxide channel layer. A gate insulation layer is formed between the gate and the oxide channel layer. A source and a drain parallel to each other are formed to connect to the oxide channel layer. A dielectric layer is formed to cover the source and the drain at a side away from the substrate.

According to an embodiment of the invention, the oxide channel layer has a first region and a second region. The metal element content in the first region is greater than the metal element content in the second region. The first region and the second region are arranged sequentially in the thickness direction. The first region is closer to the gate than the second region. The metal element content is gradually reduced from the first region to the second region.

According to an embodiment of the invention, the oxide channel layer has a first region and a second region. The metal element content in the first region is greater than the metal element content in the second region. The first region and the second region are arranged sequentially in the thickness direction. The first region is closer to the source and the drain than the second region. The metal element content is gradually reduced from the first region to the second region.

According to an embodiment of the invention, the gate is located between the oxide channel layer and the substrate.

According to an embodiment of the invention, the thin film transistor further includes an etching stop layer located at a side of the oxide channel layer in contact with the source and the drain.

According to an embodiment of the invention, the source and the drain are located between the oxide channel layer and the gate.

According to an embodiment of the invention, the oxide channel layer is located between the substrate and the gate. The thin film transistor further includes an insulation layer located at a side of the gate away from the gate insulation layer. The insulation layer has a first through hole and a second through hole, wherein the first through hole and the second through hole both pass through the insulation layer and the gate insulation layer to partially expose the oxide channel layer. The source and the drain are connected to the oxide channel layer respectively through the first through hole and the second through hole.

According to an embodiment of the invention, the metal element includes In, Zn, Cd, or Sn.

According to an embodiment of the invention, the step of forming the first semiconductor oxide layer includes performing a low temperature film forming process, wherein the temperature of the low temperature film forming process ranges from 20° C. to 150° C.

According to an embodiment of the invention, in the manufacturing method, the metal element content in the first semiconductor oxide layer is a first content and the metal element content in the second semiconductor oxide layer is a second content different from the first content.

According to an embodiment of the invention, the manufacturing method of the thin film transistor further includes performing a thermal annealing process to diffuse the metal element from the first semiconductor oxide layer to the second semiconductor oxide layer such that the gradient distribution of the metal element content substantially has a gradually change distribution to form the oxide channel layer.

In view of the above, at least two semiconductor oxide materials are used for forming the oxide channel layer in the thin film transistor and the manufacturing method thereof according to the embodiment of the invention. The first semiconductor oxide material has better resistance to acid etchant or water so as to provide the protection function to the second semiconductor oxide material. In addition, the first semiconductor oxide material has low transmittance to UV light (UV cut characteristic) so that the photo current generated by the second semiconductor oxide material during the irradiation of UV light can be reduced, which facilitates to improve the electro-optical characteristic of the thin film transistor and prolong the lifetime of the thin film transistor. In addition, the first semiconductor oxide material has high adhesion property at the interface and high carrier mobility, which facilitates to compensate the defects generated at the interface between the second semiconductor oxide material and other film layer. Accordingly, the stability, the reliability, and the electro-optical characteristic of the thin film transistor can be improved.

In order to make the aforementioned properties and advantages of the invention more comprehensible, embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A to FIG. 1F are schematic views illustrating a process of manufacturing a TFT according to an embodiment of the invention.

FIG. 2 shows the X-ray diffraction (XRD) spectrum of the indium oxide film formed under room temperature.

FIG. 3 is a schematic view showing the deposition of the indium oxide.

FIG. 4 schematically shows the on-current and off-current of a thin film transistor having the channel made by indium-gallium-zinc oxide under the irradiation of light with different wavelengths.

FIG. 5A schematically shows the transmittance of indium oxide film to light with different wavelengths.

FIG. 5B schematically shows the transmittance of zinc oxide film to light with different wavelengths.

FIG. 6A and FIG. 6B are schematic views illustrating a process of manufacturing a TFT according to another embodiment of the invention.

FIG. 7 to FIG. 11 are schematic views illustrating a TFT according to other embodiments of the invention before the thermal annealing process is performed thereon.

FIG. 12 schematically illustrates the disposition of the first semiconductor oxide layer, the second semiconductor oxide layer, and the gate insulation layer.

### DETAILED DESCRIPTION OF THE EMBODIMENTS

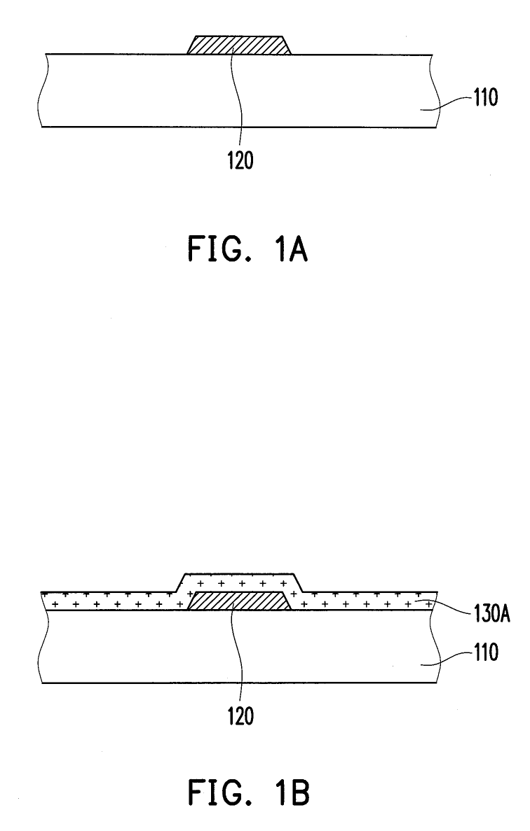

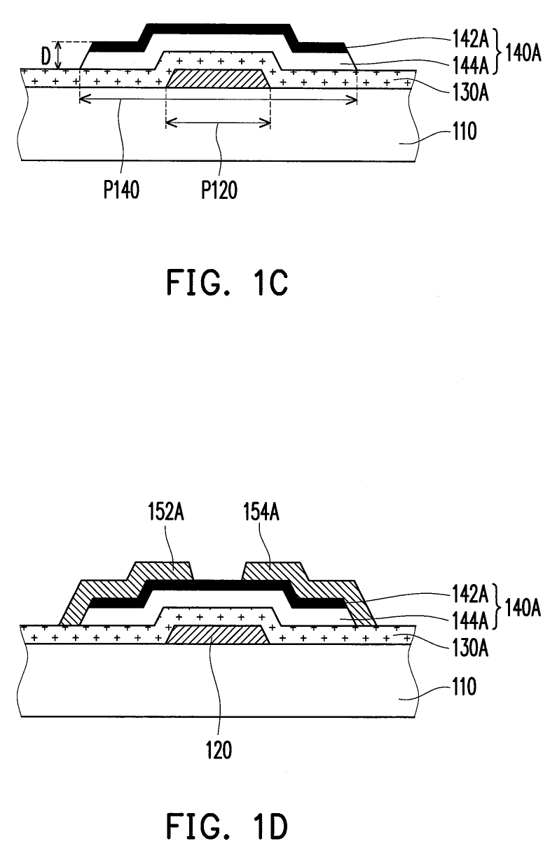

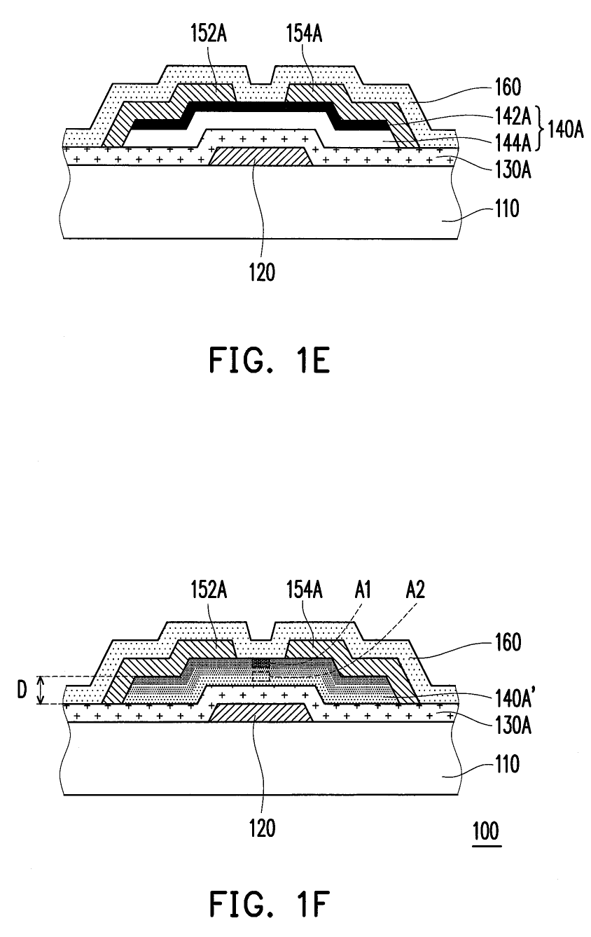

FIG. 1A to FIG. 1F are schematic views illustrating a process of manufacturing a TFT according to an embodiment of the invention.

Referring to FIG. 1A, a substrate 110 is provided and a gate 120 is formed on the substrate 110, wherein the gate 120 can be formed by a stack of metal layers or a single metal layer and the material of the gate 120 can be Al, Cu or other metals having high conductivity. It is noted that according to the requirement, the gate 120 can be made by non-metal conductive material such as Indium Tin Oxide (ITO).

Referring to FIG. 1B, a gate insulation layer 130A is formed on the substrate 110, so as to cover the gate 120. The material of the gate insulation layer 130A includes an inorganic material (e.g. silicon oxide, silicon nitride, silicon oxynitride, silicon aluminum oxide, or a stacked layer of the above materials), an organic material, or a combination of the above. It is noted that the embodiment is not limited thereto and any material having insulation property can be selected to apply in the present embodiment to form the gate insulation layer 130A.

Referring to FIG. 1C, at least one first semiconductor oxide layer 142A and at least one second semiconductor oxide layer 144A are formed on the substrate 110, wherein the first semiconductor oxide layer 142A and the second semiconductor oxide layer 144A are sequentially arranged to form an oxide channel layer 140A. In an alternate embodiment, a plurality of the first semiconductor oxide layers 142A and a plurality of second semiconductor oxide layers 144A can be used and the first semiconductor oxide layers 142A and the second semiconductor oxide layers 144A can be alternatively arranged. According to the present embodiment, the oxide channel layer 140A is formed by one first semiconductor oxide layer 142A and one semiconductor oxide layer 144A, for example. Furthermore, the material of the first semiconductor oxide layer 142A can be indium oxide and the material of the second semiconductor oxide layer 144A can be amorphous indium-gallium-zinc oxide (a-IGZO).

In addition, according to FIG. 1C, the first semiconductor oxide layer 142A covers over the second semiconductor oxide layer 144A at a side away from the gate insulation layer 130A, but the invention is not limited thereto. In another embodiment, the oxide channel layer 140A can be formed by the second semiconductor oxide layer 144A covering the first semiconductor oxide layer 142A at a side away from the gate insulation layer 130A. Alternately, the oxide channel layer 140A can be formed by a plurality of first semiconductor oxide layers 142A and a plurality of second semiconductor oxide layers 144A alternatively arranged, for example.

In the present embodiment, the gate 120 is located between the oxide channel layer 140A and the substrate 110 and the gate insulation layer 130A is located between the gate 120 and the oxide channel layer 140A so as to be a bottom gate type design. Specifically, the oxide channel layer 140A is disposed on the substrate 110 and stacked over the gate 120. In other words, the orthogonal projection P140A of the oxide channel layer 140A on the substrate 110 covers the orthogonal projection P120 of the gate 120 on the substrate 110. The area of the orthogonal projection P140A of the oxide channel layer 140A on the substrate 110 overlaps the area of the orthogonal projection P120 of the gate 120 on the substrate 110.

In addition, the material of the first semiconductor oxide layer 142A in the oxide channel layer 140A includes a metal element, i.e. the material of the first semiconductor oxide layer 142A can be a metal oxide element, wherein the metal element includes In, Zn, Cd, or Sn. In the present embodiment of the invention, the metal element is indium (In) as an example for description. Additionally, the material of the second semiconductor oxide layer 144A is different from the first semiconductor oxide layer 142A, wherein the material of the second semiconductor oxide layer 144A can be IGZO, but the invention is not limited thereto. Herein, the metal element content (In) in the first semiconductor oxide layer 142A is a first content, and the metal element content in the second semiconductor oxide layer 144A is a second content while the first content is greater than the second content. It is noted an element content as described herein means the weight percentage of the element in the total composition of the layer.

In the present embodiment, the first semiconductor oxide layer 142A and the second semiconductor oxide layer 144A can be fabricated by two independent processes so that the metal (In) content in the stack (the oxide channel layer 140A) consisting of the first semiconductor oxide layer 142A and the second semiconductor oxide layer 144A has a non-continuous distribution. Specifically, the metal (In) content of the oxide channel layer 140A shows a gradient distribution (e.g. gradient concentration distribution) having a significant change from the first semiconductor oxide layer 142A to the second semiconductor oxide layer 144A in the thickness direction. It is for sure that the invention should not be construed as limited to the embodiment described above.

Next, referring to FIG. 1D, a source 152A and a drain 154A is formed on the oxide channel layer 140A, wherein the source 152A and the drain 154A are configured parallel to each other and connected to the oxide channel layer 140A. In the present embodiment, the source 152A and the drain 154A are, for example, formed by a stack of multiple metal layers or formed by a signal metal layer and a material thereof can be metal materials such as Al, Cu, Ag, or other metals having good conductivity. It is noted that the source 152A and the drain 154A can be made by non-metal conductive material.

Referring to FIG. 1E, a dielectric layer 160 covering the source 152A and the drain 154A at a side away from the substrate 110 is subsequently formed. The material of the dielectric layer 160 includes an inorganic material (e.g. silicon oxide, silicon nitride, silicon oxynitride, silicon aluminum oxide, or a stacked layer of at least two materials aforementioned above), an organic material, or a combination of the above. It is noted that the embodiment is not limited thereto and any material having insulation property can be selected to apply in the present embodiment to form the dielectric layer 160.

Referring to FIG. 1F, a thermal annealing process is performed so as to construct the thin film transistor 100. Herein, the metal element (In) in the first semiconductor oxide layer 142A can be diffused to the second semiconductor oxide layer 144A by the thermal annealing process so that the metal (In) content can have a gradually changed distribution to form the oxide channel layer 140A′. Regarding to different regions arranged along the thickness direction D of the oxide channel layer 140A, the oxide channel layer 140A has a first region A1 and a second region A1, wherein the first region A1 is farther from the gate 120 than the second region A2. The metal (In) content in the first region A1 is greater than that in the second region A2. That is, the metal content of the oxide channel layer 140A′ is gradually reduced from the first region A1 to the second region A2. In other words, the metal content of the oxide channel layer 140A′ is gradually reduced from a side adjacent to the source 152A and the drain 154A to another side adjacent to the gate insulation layer 130A.

It is noted that the oxide channel layer 140A according to the present embodiment has the stack structure of a plurality of layers at least including the first semiconductor oxide layer 142A and the second semiconductor oxide layer 144A with different materials. After performing the thermal annealing process, the element, such as In, can be diffused from the first semiconductor oxide layer 142A to the second semiconductor oxide layer 144A to form the oxide channel layer 140A′ substantially having a single layer structure. As such, the thin film transistor 100 of the present embodiment can have better stability and reliability because the property of the oxide channel layer 140A is not liable to be influenced by the sharp interface between different two semiconductor layers.

In addition, the element content of the first semiconductor layer 142A is similar to that of the second semiconductor layer 144A but the first semiconductor layer 142A and the second semiconductor oxide layer 144A can have different characteristics. In one instance, the carrier mobility of indium oxide is higher than that of IGZO, so that the first semiconductor oxide layer 142A can have higher carrier mobility than the second semiconductor oxide layer 144A. Herein, the metal element (In) in the first semiconductor oxide layer 142A can be diffused to the second semiconductor oxide layer 144A by the thermal annealing process so that the metal (In) content in the second semiconductor oxide layer 144A is increased. Therefore, the oxide channel layer 140A′ can have an improved carrier mobility so as to enhance the on-current of the thin film transistor 100.

Nevertheless, the first semiconductor oxide layer 142A and the second semiconductor oxide layer 144A have different characteristics. The first semiconductor oxide layer 142A and the second semiconductor oxide layer 144A respectively used as the channels of two thin film transistors can render the two thin film transistors have different characteristics such as different off-currents. If the oxide channel layer 140A′ have the semiconductor property similar to the second semiconductor oxide layer 144A, the thin film transistor 100 can have desirable off-current. Therefore, the first semiconductor oxide layer 142A can be designed to have a thickness from about 20 Å to about 100 Å by adjusting the fabrication condition of forming the first semiconductor oxide layer 142A. The amount of the metal element (In) in the first semiconductor oxide layer 142A diffused to the second semiconductor oxide layer 144A by the thermal annealing process can be controlled in a suitable level so that the off-current of the thin film transistor 100 having the oxide channel 140A′ is satisfactory. Consequently, the thin film transistor 100 of the present embodiment can have higher on/off current ratio under the increase of the on-current without significantly changing the off-current.

Furthermore, the electric characteristic and the uniformity of the second semiconductor oxide layer 144A made of IGZO are liable to be changed by the environment and the manufacturing processes. Therefore, the first semiconductor oxide layer 142A made of indium oxide can be selected to be formed at room temperature and under low energy. For example, the step of forming the first semiconductor oxide layer 142A can include performing a low temperature film forming process, and a fabrication temperature of the low temperature film forming process ranges from 20° C. to 150° C. Owing that the indium oxide and IGZO are manufactured at room temperature, the manufacturing method according to the present embodiment can be applied to form the oxide channel layer on a flexible substrate or a plastic substrate which has poor resistance to temperature.

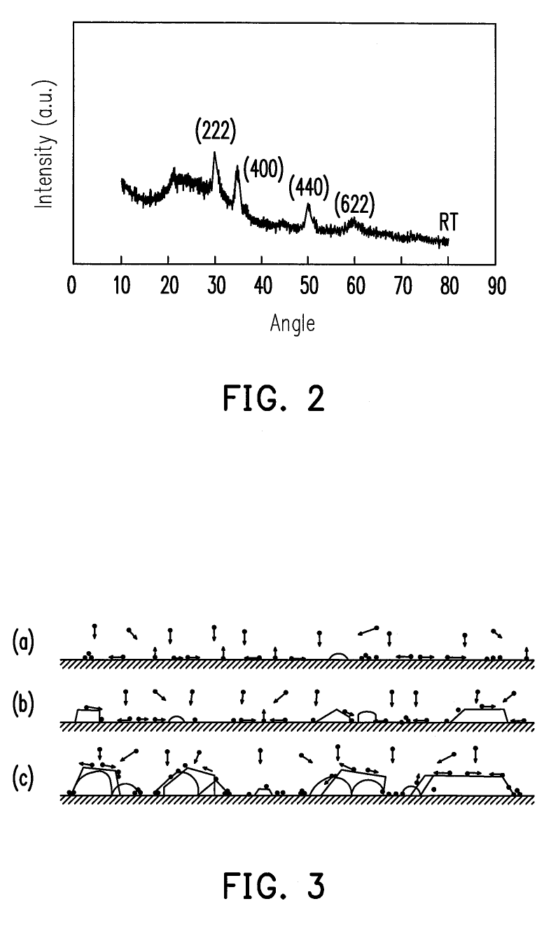

The manufacturing process, the structure and the effect of the first semiconductor oxide layer before the thermal annealing process is further described in the following accompanying with FIG. 2 to FIG. 5.

FIG. 2 shows the X-ray diffraction (XRD) spectrum of the indium oxide film formed under the room temperature and FIG. 3 is a schematic view showing the deposition of the indium oxide film. As shown in FIG. 2 and FIG. 3, the indium oxide film has micro-crystalline structure if formed by a sputtering process at room temperature and low energy, wherein the indium oxide formed on the substrate constructs the island-like structures. The micro crystalline structure of indium oxide film facilitates the improvement of the carrier mobility of the first semiconductor oxide layer. Therefore, the on-current of the thin film transistor 100 depicted in FIG. 1F can be enhanced by forming the first semiconductor oxide layer 142A illustrated in FIG. 1C and FIG. 1D through the sputtering process at room temperature and low energy.

In addition, the micro crystalline indium oxide film (such as the first semiconductor oxide layer 142A) has the resistance to the dry or wet etchant better than the amorphous IGZO film (such as the second semiconductor oxide layer 144A). Therefore, during the manufacturing process depicted in FIG. 1A through FIG. 1F, the indium oxide film (such as the first semiconductor oxide layer 142A) can provide the protection function to the amorphous IGZO (such as the second semiconductor oxide layer 144A) when the film layers (such as the source 152A and the drain 154A) formed after the oxide channel layer 140A are patterned. Specifically, the electric property and uniformity of the amorphous IGZO film (such as the first semiconductor oxide layer 142A) are not liable to be changed due to the reaction with the etchant. Accordingly, the manufacturing conditions for patterning the film layers (such as the source 152A and the drain 154A) formed after the oxide channel layer 140A can have greater flexibility so as to improve the capability of mass production and the yield rate.

In addition, the indium oxide film and the IGZO film have similar compositions and the surface adhesion therebetween is good so that the indium oxide film can be directly formed on the IGZO film and no additional treatment is required. The indium oxide film is not liable to be oxidized by water vapor in the environment if compared with IGZO film. Accordingly, the disposition of the first semiconductor oxide layer 142A on the second semiconductor oxide layer 144A facilitates to reduce the defects generated on the surface of the second semiconductor oxide layer 144A owing to the oxidation effect or the interaction with water vapor, which conduces to reduce the contact resistance when the oxide channel layer 140A is in contact with the source 152A and the drain 154A.

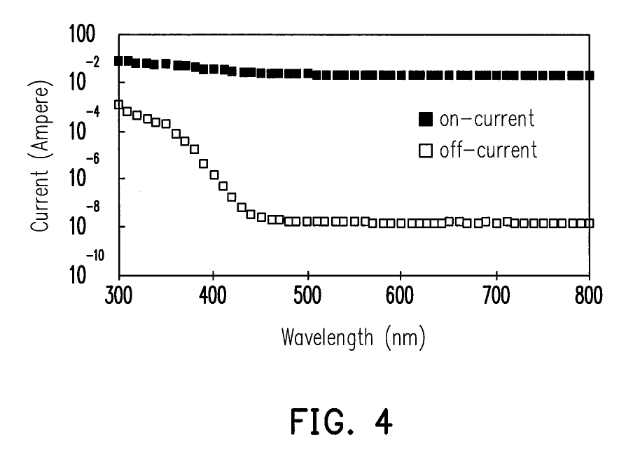

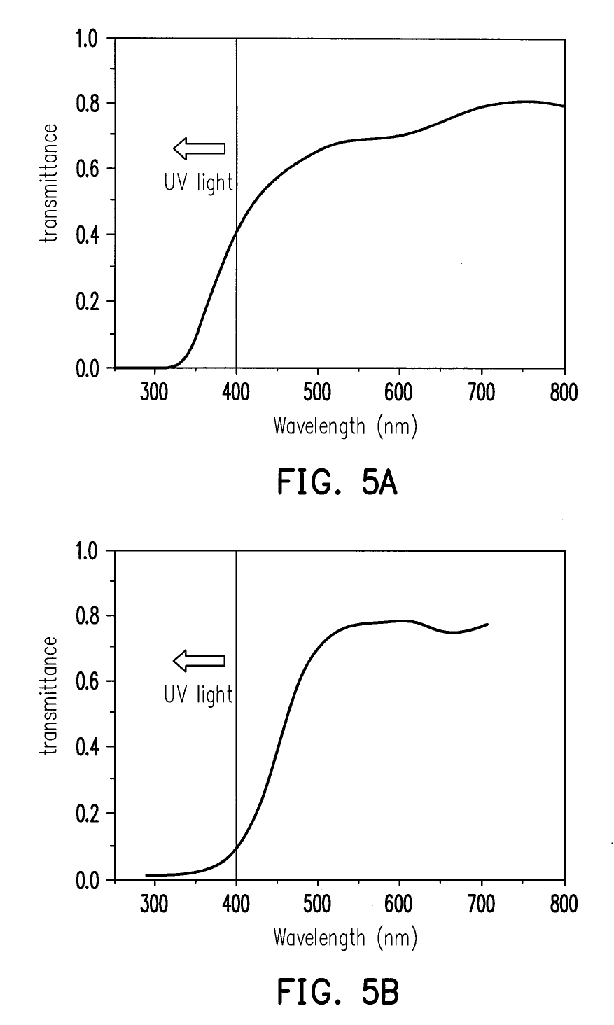

The on-currents and the off-currents of transistors having the micro crystalline indium oxide channel layer and the IGZO channel layer respectively under irradiation of the light with different wavelengths are further described in the following. FIG. 4 schematically shows the curves of the on-current and the off-current of a transistor having an oxide channel layer under irradiation of light with different wavelengths, wherein the composition of the oxide channel layer is substantially uniformed IGZO. FIG. 5A schematically shows the transmittance of indium oxide film to light with different wavelengths.

Referring to FIG. 4, the photo current is generated under the irradiation of the UV light (the wavelength of the UV light is smaller than 400 nm) when the substantially uniformed IGZO film is served as the oxide channel layer of the thin film transistor in the turn off state. However, as shown in FIG. 5, the transmittance of light having the wavelength ranged at the UV light (smaller than 400 nm) in the indium oxide film is significantly reduced. Therefore, the indium oxide film has the blocking function to light having the wavelength range of the UV light. In the thin film transistor 100 manufactured by the processes depicted in FIG. 1A through FIG. 1F, the disposition of the indium oxide film (the first semiconductor oxide layer 142A) at a side of the IGZO film (the second semiconductor oxide layer 144A) away from the substrate 100 or adjacent to the source 152A and the drain 154A can conduce to block the UV light irradiating on the second semiconductor oxide layer 144A. Thereby, the photo current generated by the oxide channel layer 140A or 140A′ under the irradiation of the UV light is eliminated so as to improve the lifetime of the TFT and the element characteristic of the thin film transistor 100.

It is noted that the embodiment according to the invention does not limit to apply the indium oxide film as the material blocking the UV light. FIG. 5B schematically shows the transmittance of zinc oxide film to light with different wavelengths. As shown in FIG. 5B, the zinc oxide film has the blocking function to light having the wavelength range of the UV light. Accordingly, in the thin film transistor 100 manufactured by the processes depicted in FIG. 1A through FIG. 1F, the disposition of the zinc oxide film (the first semiconductor oxide layer 142A) at a side of the IGZO film (the second semiconductor oxide layer 144A) away from the substrate 100 or adjacent to the source 152A and the drain 154A can conduce to block the UV light irradiating on the second semiconductor oxide layer 144A.

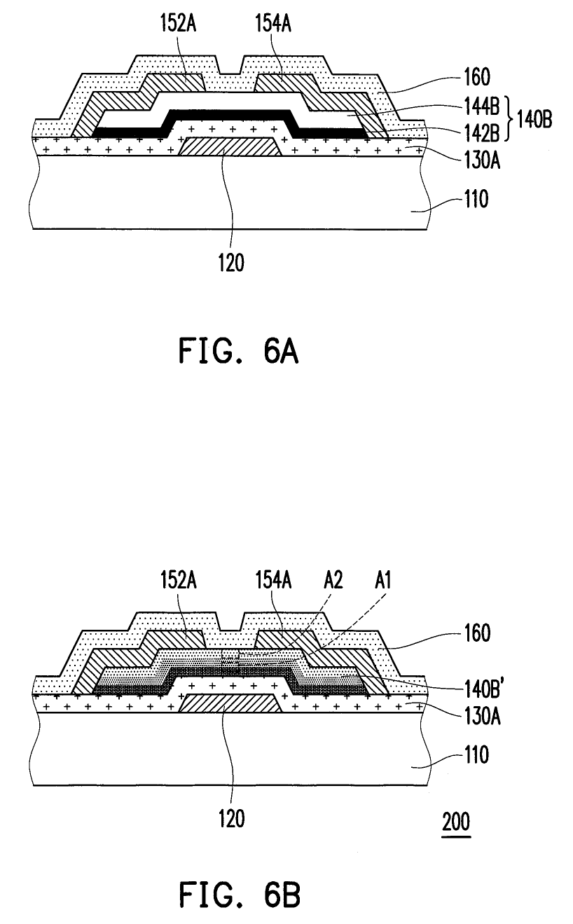

In another embodiment for forming a bottom gate type thin film transistor, the first semiconductor oxide layer can be disposed at a side of the second semiconductor oxide layer adjacent to the gate. FIG. 6A and FIG. 6B are schematic views illustrating a process of manufacturing a TFT according to another embodiment of the invention.

With reference to FIG. 6A, the processes depicted in the embodiment is similar to those shown in FIG. 1A through FIG. 1F, and thus the same components in these drawings are denoted by the same numerals and are not reiterated herein. The difference between the two embodiments mainly lies in that the stacking sequence of the first semiconductor oxide layer 142B and the second semiconductor oxide layer 144B in the present embodiment is different from those depicted in FIG. 1C.

Particularly, the method for forming the oxide channel layer 140B according to the embodiment shown in FIG. 6A includes forming the first semiconductor oxide layer 142B on the gate insulation layer 130A and subsequently forming the second semiconductor oxide layer 144B covering the first semiconductor oxide layer 142B, for example. Therefore, in the oxide channel layer 140B, the first semiconductor oxide layer 142B having higher metal (In) content is closer to the gate 120 than the second semiconductor oxide layer 144B.

It is noted that in the structure of the thin film transistor having the oxide channel layer only made of IGZO, the oxide channel layer has poor adhesion property with the gate insulation layer. Charges are liable to be accumulated at the interface between the gate insulation layer and the oxide channel layer to form a conductive path if the thin film transistor has the oxide channel layer only made of IGZO, which deteriorates the element characteristic of the thin film transistor. Therefore, in the present embodiment, the first semiconductor oxide layer 142B (such as the micro crystalline indium oxide film) is formed between the gate insulation layer 130A and the second semiconductor oxide layer 144B, which improves the adhesion at the interface between the gate insulation layer 130A and the oxide channel layer 140B so as to eliminate the problem caused by charge accumulation.

Referring to FIG. 6A and FIG. 6B, a thermal annealing process is performed so as to construct the thin film transistor 200. Herein, the metal element (In) in the first semiconductor oxide layer 142B can be diffused to the second semiconductor oxide layer 144B by the thermal annealing process. Therefore, the metal (In) content can have a gradually changed distribution to form the oxide channel layer 140B′. That is, the metal content of the oxide channel layer 140B′ is gradually reduced from the first region A1 adjacent to the gate 120 to the second region A2 adjacent to the source 152A and the drain 154A.

Similar to those depicted in FIG. 1F, the metal element (In) in the first semiconductor oxide layer 142B can be diffused to the second semiconductor oxide layer 144B by the thermal annealing process so that the metal (In) content in the second semiconductor oxide layer 144B is increased. Therefore, by properly controlling the design of the first semiconductor layer 142B (rendering the thickness of the first semiconductor oxide layer 142B ranging from 5 Å to 200 Å, for example), the oxide channel layer 140B′ can have desirable carrier mobility to improve the on-current of the thin film transistor 200. Simultaneously, the thin film transistor having the oxide channel layer 140B′ can have the off-current similar to thin film transistor having the oxide channel layer only made of IGZO. Accordingly, the thin film transistor 200 of the present embodiment can have higher on/off current ratio.

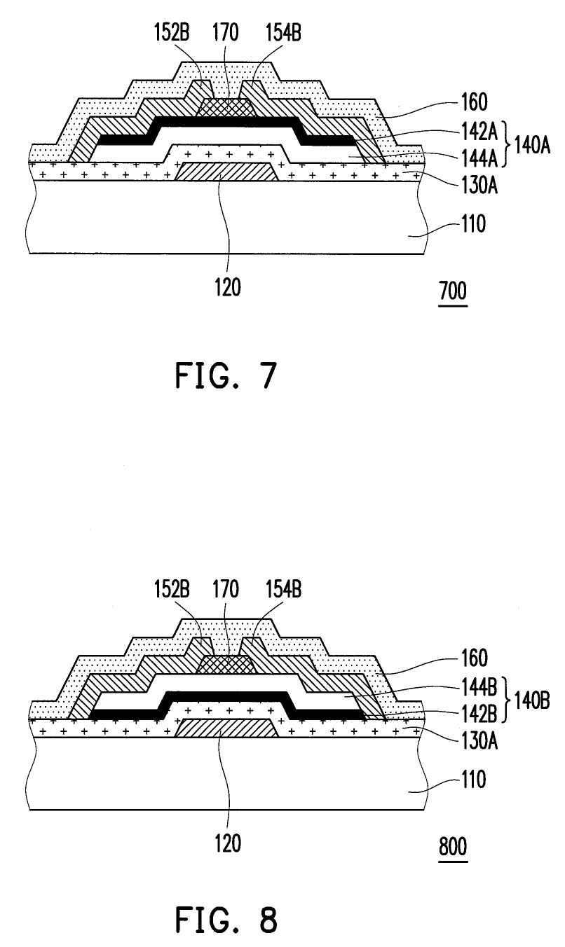

Certainly, the above-mentioned thin film transistors 100 and 200 are merely exemplary and should not be construed as limitations to this invention. FIG. 7 through FIG. 11 further schematically illustrate the structure designs of the thin film transistors according to other embodiments. It is noted that the oxide channel layers depicted in the following embodiments are not subjected to the thermal annealing process for descriptive purpose. However, the oxide channel layers in those embodiments can be further subjected to the thermal annealing process as depicted in FIG. 1F according to the design.

As shown in FIG. 7, the thin film transistor 700 can further include an etching stop layer 170 located at a side of the oxide channel layer 140A, wherein the side is in contact with the source 152B and the drain 154B. Similarly, referring to FIG. 8, the thin film transistor 800 can further include an etching stop layer 170 located at a side of the oxide channel layer 140B, wherein the side is in contact with the source 152B and the drain 154B. It is noted that the structure designs of the thin film transistor 700 and the thin film transistor 800 depicted in FIG. 7 and FIG. 8 are similar, except for the disposition sequence of the first semiconductor oxide layer and the second semiconductor oxide layer. Specifically, in the thin film transistor 700, the first semiconductor oxide layer 142A is located at a side of the second semiconductor oxide layer 144A away from the gate 120 while the first semiconductor oxide layer 142B of the thin film transistor 800 is located at a side of the second semiconductor oxide layer 144B adjacent to the gate 120.

The thin film transistor 700 in FIG. 7 before and after the oxide channel layer 140A is subjected to the thermal annealing process can have the characteristics of the thin film transistor 100 as depicted in FIGS. 1D and 1F, respectively. It is noted that the oxide channel layer 140A according to the present embodiment includes the first semiconductor oxide layer 142A covering over the second semiconductor oxide layer 144A (i.e. the first semiconductor layer 142A is located at a side of the second semiconductor oxide layer 144A away from the gate 120) before subjected to the thermal annealing process, which facilitates to protect the second semiconductor oxide layer 144A, increase the flexibility of the subsequent processes, and reduce the contact resistance of the oxide channel layer 140A in contact with the source 152A and the drain 154A. Herein, the metal element (In) in the first semiconductor oxide layer 142A can be diffused to the second semiconductor oxide layer 144A by the thermal annealing process so that the thin film transistor 700 can have desirable carrier mobility, stability, and reliability.

The thin film transistor 800 in FIG. 8 before and after the oxide channel layer 140B is subjected to the thermal annealing process can have the characteristics of the thin film transistor 200 as depicted in FIGS. 6A and 6B, respectively. Particularly, the first semiconductor oxide layer 142B of the oxide channel layer 140B is disposed between the second semiconductor oxide layer 144B and the gate insulation layer 130A, which facilitates to increase the adhesion between the oxide channel layer 140B and the gate insulation layer 130A and improve the carrier mobility of the oxide channel layer 140B. Herein, the metal element (In) in the first semiconductor oxide layer 142B can be diffused to the second semiconductor oxide layer 144B by the thermal annealing process so that the thin film transistor 800 can have desirable carrier mobility, stability, and reliability.

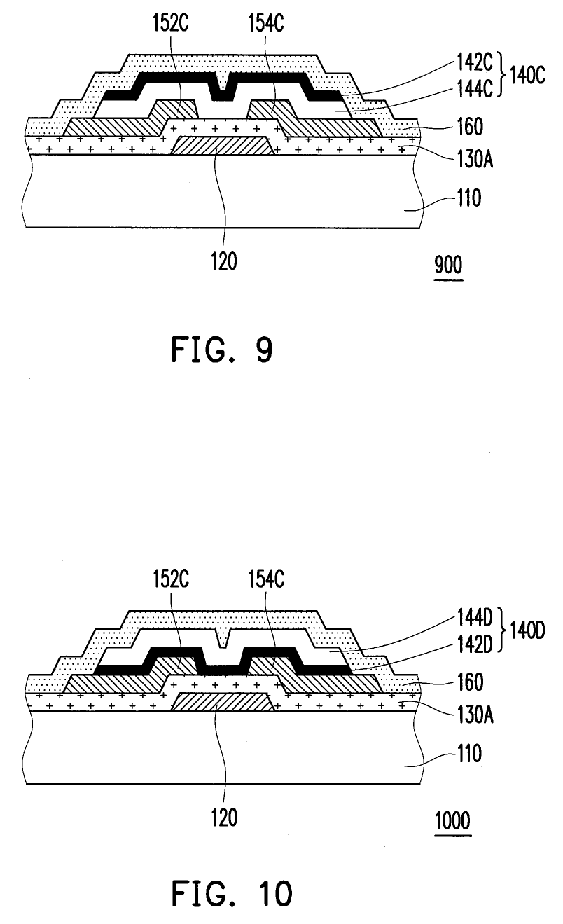

Furthermore, as shown in FIG. 9 and FIG. 10, the source 152C and the drain 154C in the thin film transistor 900 and the thin film transistor 1000 can be co-planar. According to the embodiments, the source 152C and the drain 154C are configured parallel to each other and located between the oxide channel layer 140C and the gate 120 in the thin film transistor 900 while the source 152C and the drain 154C are configured parallel to each other and located between the oxide channel layer 140D and the gate 120 in the thin film transistor 1000. It is noted that the structure design of the thin film transistor 900 and the thin film transistor 1000 depicted in FIG. 9 and FIG. 10 are similar, except for the disposition sequence of the first semiconductor oxide layer and the second semiconductor oxide layer. Specifically, in the thin film transistor 900, the first semiconductor oxide layer 142C is located at a side of the second semiconductor oxide layer 144C away from the gate 120 while the first semiconductor oxide layer 142D of the thin film transistor 1000 is located at a side of the second semiconductor oxide layer 144D adjacent to the gate 120.

The thin film transistor 900 in FIG. 9 before and after the oxide channel layer 140C is subjected to the thermal annealing process can have the characteristics of the thin film transistor 100 as depicted in FIGS. 1D and 1F, respectively. The thin film transistor 1000 in FIG. 10 before and after the oxide channel layer 140D is subjected to the thermal annealing process, similar to the thin film transistor 800, can have the characteristics of the thin film transistor 200 as depicted in FIGS. 6A and 6B, respectively. No further description is provided herein, since reference can be directed to the description of FIG. 7 and FIG. 8.

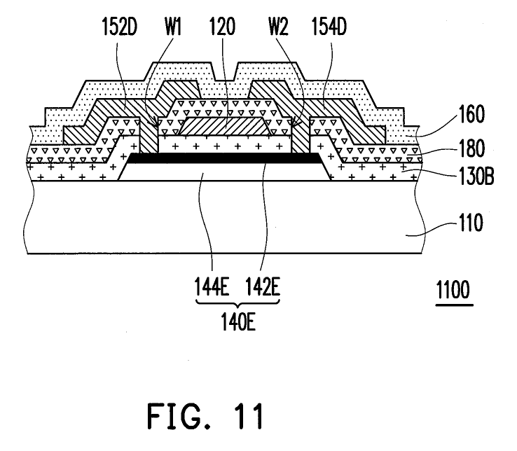

As shown in FIG. 11, the structure of the thin film transistor can have a top gate design. In the embodiment, the second semiconductor oxide layer 144E is disposed on the substrate 110 and the first semiconductor oxide layer 142E covers the second semiconductor oxide layer 144E, wherein the first semiconductor oxide layer 142E and the second semiconductor oxide layer 144E together form the oxide channel layer 140E located between the substrate 110 and the gate 120. The gate insulation layer 130B covers the substrate 110 and located at a side of the oxide channel layer 140E away from the substrate 110. The gate 120 is disposed above the gate insulation layer 130B and stacked over the oxide channel layer 140E in a top and bottom manner.

In addition, the thin film transistor 110 can further include an insulation layer 180 located at a side of the gate 120 away from the gate insulation layer 130B and a first through hole W1 and a second through hole W2 are formed in the thin film transistor 1100. The first through hole W1 and the second through hole W2 both pass through the insulation layer 180 and the gate insulation layer 130B to expose portions of the oxide channel layer 140E respectively. According to the present embodiment, the first through hole W1 and the second through hole W2 expose portions of the first semiconductor oxide layer 142E of the oxide channel layer 140E. The source 152D and the drain 154D are configured parallel to each other and located at a side of the insulation layer 180 away from the gate insulation layer 130B. The source 152D and the drain 154D are connected to the oxide channel layer 140E through the first through hole W1 and the second through hole W2. The dielectric layer 160 covers the source 152D and the drain 154D at a side away from the substrate 110.

According to the present embodiment, the first semiconductor oxide layer 142E is formed covering over the second semiconductor oxide layer 144E in the thin film transistor 1100. The first semiconductor oxide layer 142E, similar to the design of the thin film transistor 100, can be served as a protection layer protecting the second semiconductor oxide layer 144E and facilitates to improve the flexibility of the subsequent processes and reduce the contact resistance of the oxide channel layer 140E in contact with the source 152D and the drain 154D.

For instance, it is generally known that the etchant for forming the first through hole W1 and the second through hole W2 is liable to etch the second semiconductor oxide layer 144E made of IGZO. Nevertheless, the first semiconductor oxide layer 142E according to the thin film transistor 1100 of the embodiment can be served as a protection layer protecting the second semiconductor oxide layer 144E and facilitates to prevent the second semiconductor oxide layer 144E from change in the electric characteristic and the stability by reacting with the composition of the plasma.

Additionally, the first semiconductor oxide layer 142E of the thin film transistor 1100 is located between the gate insulation layer 130B and the second semiconductor oxide layer 144E. Therefore, similar to the thin film transistor 200, the adhesion at the interface between the gate insulation layer 130B and the second semiconductor oxide layer 144E and the carrier mobility of the thin film transistor 1100 can be improved.

The metal element (In) in the first semiconductor oxide layer 142E can be diffused to the second semiconductor oxide layer 144E by the thermal annealing process so that the metal (In) content in the second semiconductor oxide layer 144E is increased. Thereby, the thin film transistor 110 has desirable carrier mobility, stability and reliability.

In the forgoing embodiments, the oxide channel layers 140A, 140B, 140C, 140D or 140E of the thin film transistors 100, 200, 700, 800, 900, 1000, or 1100 are designed as a structure stacked by one first semiconductor oxide layer 142A, 142B, 142C, 142D, or 142E and one second semiconductor oxide layer 142A, 142B, 142C, 142D, or 142E. However, the invention is not limited thereto. In an alternate embodiment, the oxide channel layer can be formed by more than three semiconductor layers, i.e. the oxide channel layer can include a plurality of first semiconductor oxide layers and/or a plurality of second semiconductor oxide layers, wherein the first semiconductor oxide layers and the second semiconductor oxide layers can be alternatively arranged.

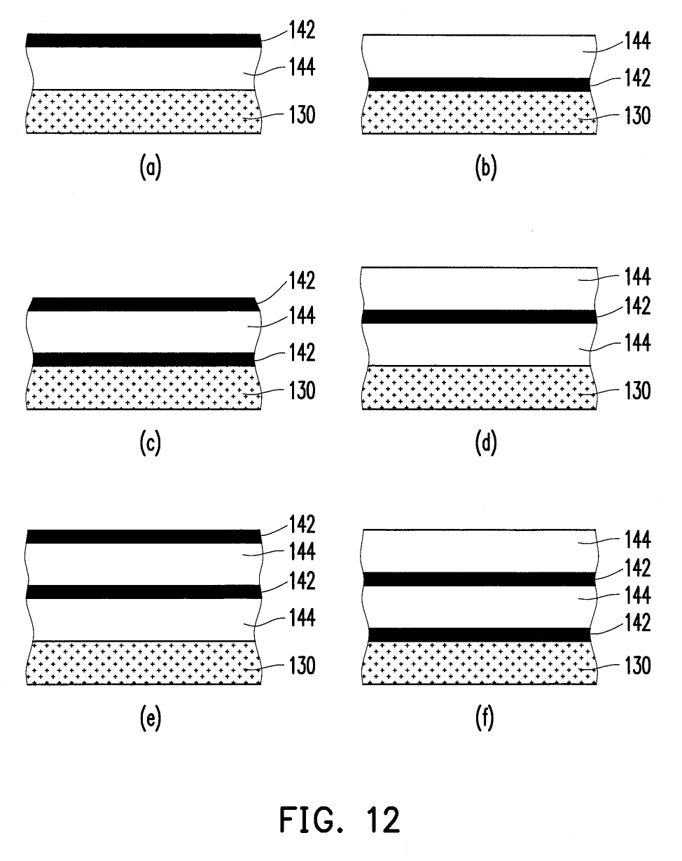

Several examples are provided in the following accompanying with FIG. 12 for describing the designs of the oxide channel layers. FIG. 12 schematically illustrates the disposition of the first semiconductor oxide layer, the second semiconductor oxide layer, and the gate insulation layer.

Referring to FIG. 12(a), the oxide channel layer is formed by one first semiconductor layer 142 and one second semiconductor layer 144, wherein the second semiconductor oxide layer 144 is located between the first semiconductor oxide layer 142 and the gate insulation layer 130. Accordingly, similar to the design shown in FIG. 1D, the first semiconductor oxide layer 142 protects the second semiconductor oxide layer 144 before the thermal annealing process. In addition, after the thermal annealing process, desirable carrier mobility can be achieved.

Referring to FIG. 12(b), the oxide channel layer is formed by one first semiconductor layer 142 and one second semiconductor layer 144, wherein the first semiconductor oxide layer 142 is located between the second semiconductor oxide layer 144 and the gate insulation layer 130. Accordingly, similar to the design shown in FIG. 6A, the first semiconductor oxide layer 142 facilitates to improve the interface adhesion between the gate insulation layer 130 and the second semiconductor oxide layer 144 and improve the carrier mobility. In addition, after the thermal annealing process, desirable carrier mobility can be achieved.

Referring to FIG. 12(c), the oxide channel layer is formed by two first semiconductor layers 142 and one second semiconductor layer 144, wherein the first semiconductor oxide layers 142 are respectively located at two opposite sides of the second semiconductor oxide layer 144 and one of the first semiconductor oxide layers 142 is located between the second semiconductor oxide layer 144 and the gate insulation layer 130. It is noted that the design according to the present embodiment have both the characteristics of the designs of FIG. 12(a) and FIG. 12(b).

Referring to FIG. 12(d), the oxide channel layer is formed by one first semiconductor layer 142 and two second semiconductor layers 144, wherein the second semiconductor oxide layers 144 are respectively located at two opposite sides of the first semiconductor oxide layer 142 and one of the second semiconductor oxide layers 144 is located between the first semiconductor oxide layer 142 and the gate insulation layer 130. By disposing one first semiconductor oxide layer 142 between two second semiconductor oxide layers 144, the metal (indium) content in the second semiconductor layer 144 can be increased after the thermal annealing process so that the oxide channel layer can have desirable carrier mobility.

Referring to FIG. 12(e) and FIG. 12(f), the oxide channel layer is formed by two first semiconductor layers 142 and two second semiconductor layers 144, wherein the first semiconductor oxide layers 142 and the second semiconductor oxide layers 144 are alternately arranged. According to the embodiments, the oxide channel layer can be selectively formed by stacking of three first semiconductor oxide layers 142 and two semiconductor oxide layers 144 or by other stacking methods.

In light of the foregoing, the first semiconductor oxide layer having the characteristics such as acid resistance, UV blocking, or the like, is manufactured at a side of the second semiconductor oxide layer to provide desirable protection function according to the thin film transistor and the manufacturing method in the embodiments of the invention. Therefore, during patterning the oxide channel layer or patterning the film layers over the oxide channel layer, the second semiconductor layer is prevented from damaged by the etchant or the irradiation of UV light which causes the change in electro-optical characteristics, the uniformity and lift time of the second semiconductor layer. In addition, the first semiconductor oxide material has high adhesion property at the interface and high carrier mobility, which facilitates to compensate the defects at the interface between the oxide channel layer and other film layer and reduce the contact resistance of the oxide channel layer in contact with the source and the drain. Furthermore, the metal (indium, for example) content in the second semiconductor oxide layer is slightly increased by the thermal annealing process so that the oxide channel layer has better carrier mobility, which conduces to improve the on-current of the thin film transistor without changing the off-current significantly so as to achieve higher on/off current ratio.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor, comprising:
a gate disposed on a substrate;
an oxide channel layer disposed on the substrate and stacked with the gate in a top and bottom manner, wherein a material of the oxide channel layer comprises a metal element and the metal element content has a gradient distribution in a thickness direction of the oxide channel layer;
a gate insulation layer disposed between the gate and the oxide channel layer;
a source;
a drain configured parallel to the source and the source and the drain being connected to the oxide channel layer; and
a dielectric layer covering the source and the drain at a side away from the substrate.

2. The thin film transistor as claimed in claim 1, wherein the oxide channel layer has a first region and a second region, the metal element content in the first region is greater than the metal element content in the second region while the first region and the second region are sequentially arranged along the thickness direction and the first region is closer to the gate than the second region, and the metal element content is substantially gradually reduced from the first region to the second region.

3. The thin film transistor as claimed in claim 1, wherein the oxide channel layer has a first region and a second region, the metal element content in the first region is greater than the metal element content in the second region while the first region and the second region are sequentially arranged along the thickness direction and the first region is closer to the source and the drain than the second region, and the metal element content is substantially gradually reduced from the first region to the second region.

4. The thin film transistor as claimed in claim 1, wherein the gate is disposed between the oxide channel layer and the substrate.

5. The thin film transistor as claimed in claim 4, further comprising an etching stop layer located at a side of the oxide channel layer, wherein the side is in contact with the source and the drain.

6. The thin film transistor as claimed in claim 4, wherein the source and the drain are disposed between the oxide channel layer and the gate.

7. The thin film transistor as claimed in claim 1, wherein the oxide channel layer is located between the substrate and the gate, the thin film transistor further comprises an insulation layer located at a side of the gate away from the gate insulation layer, the insulation layer has a first through hole and a second through hole passing through the insulation layer and the gate insulation layer to partially expose the oxide channel layer, and the source and the drain are connected to the oxide channel layer through the first through hole and the second through hole.

8. The thin film transistor as claimed in claim 1, wherein the metal element comprises In, Zn, Cd, or Sn.

9. A manufacturing method of a thin film transistor (TFT), comprising:
forming a gate on a substrate;
forming at least one first semiconductor oxide layer and at least one second semiconductor oxide layer on the substrate, wherein the at least one first semiconductor oxide layer and the at least one second semiconductor oxide layer are alternately arranged to form an oxide channel layer, the oxide channel layer is disposed on the substrate and stacked with the gate in a top and bottom manner, a material of the oxide channel layer comprises a metal element, and the metal element content has a gradient distribution in a thickness direction of the oxide channel layer;
forming a gate insulation layer between the gate and the oxide channel layer;
forming a source and a drain, wherein the source and the drain are configured parallel to each other and connected to the oxide channel layer; and
forming a dielectric layer covering the source and the drain at a side away from the substrate.

10. The manufacturing method of the TFT as claimed in claim 9, wherein the step of forming the first semiconductor oxide layer comprises:
performing a low temperature film forming process, and a fabrication temperature of the low temperature film forming process ranges from 20° C. to 150° C.

11. The manufacturing method of the TFT as claimed in claim 9, wherein the metal element content in the at least one first semiconductor oxide layer is a first content, the metal element content in the at least one second semiconductor oxide layer is a second content different to the first content.

12. The manufacturing method of the TFT as claimed in claim 11, further comprising performing a thermal annealing process to diffuse the metal element from the at least one first semiconductor oxide layer to the at least one second semiconductor oxide layer so that the gradient distribution of the metal element content is substantially a gradual change distribution to form the oxide channel layer.
